(19) United States
(12) Patent Application Publication
(10) Pub. No.: US 2025/0151312 A1
(43) Pub. Date: May 8, 2025

(54) Semiconductor Processing Method and Semiconductor Component Obtainable by Applying the Method

(71) Applicant: IMEC VZW, Leuven (BE)

(72) Inventors: Sachin Yadav, Leuven (BE); Bernardette Kunert, Gemmenich (BE); Bjorn Vermeersch, Heverlee (BE); Bertrand Parvais, Nil-Saint-Vincent (BE); Abhitosh Vais, Heverlee (BE); Guillaume Boccardi, Sint-Lambrechts-Woluwe (BE); Annie Kumar, Leuven (BE)

(21) Appl. No.: 18/934,774

(22) Filed: Nov. 1, 2024

(30) Foreign Application Priority Data
Nov. 3, 2023 (EP) 23207649.7

(51) Int. Cl. H01L 29/778; H01L 29/66; H01L 29/737

(52) U.S. Cl. CPC H10D 30/475; H10D 10/021; H10D 10/891; H10D 30/015

(57) ABSTRACT

Example embodiments relate to semiconductor processing methods and semiconductor components obtainable by applying the semiconductor processing methods. One example method includes providing a substrate formed of a first semiconductor material. The method also includes providing a mesa structure on the substrate and in direct contact with the substrate. The mesa structure is isolated on all lateral sides by dielectric material. Active layers of a semiconductor device are integrated in an upper portion of the mesa structure. Additionally, the method includes producing one or more openings through the dielectric material. Further, the method includes forming a cavity by removing a bottom portion of the mesa structure through the one or more openings or removing the dielectric material in a region directly adjacent to the bottom portion of the mesa structure. In addition, the method includes obtaining a thermally conductive volume by filling the cavity with a material of high thermal conductivity.

### CROSS-REFERENCE TO RELATED APPLICATIONS

The present application is a non-provisional patent application claiming priority to European Patent Application No. EP 23207649.7, filed Nov. 3, 2023, the contents of which are hereby incorporated by reference.

### FIELD OF THE DISCLOSURE

The present disclosure is related to production processes for the fabrication of semiconductor devices. The disclosure is particularly useful for the production of high-power compound semiconductor devices such as HBTs (Heterojunction Bipolar Transistor) and III-V based HEMTs (High-Electron-Mobility Transistor).

### BACKGROUND

III-V devices fabricated with materials such as InP and GaAs are key devices for radio frequency (RF) and millimetre Wave (mmWave) wireless communications. In an RF or mmWave transceiver front end module (FEM), III-V HBTs are used to implement power amplifiers and III-V HEMTs are used for either power or low-noise amplifiers. One key challenge hindering power device performance is the high junction temperatures at which these devices operate. In addition to device instantaneous performance, a high junction temperature is detrimental for device reliability. Many research groups have attempted to reduce the operating junction temperature in power devices. These include device front and back-end as well as packaging level solutions. Device front-end solutions include replacing thermally resistive material layers with more thermally conductive ones. In the back-end processing, the solutions include using heat spreading dielectric layers e.g. diamond layers, and metal thermal shunts.

Another solution is achieved through wafer bonding where the device is transferred to a high thermal conductivity substrate. For example, document “InP HBT substrate transferred to higher thermal conductivity substrate”, Dennis W Scott et al, IEEE EDL, Vol. 33, No. 4. 2012, describes a method wherein HBTs are transferred to a high thermal conductivity SiC substrate. In this approach the output terminal (usually collector in case of HBTs) is in contact with the high conductivity substrate which improves the heat flow as compared to a monolithic approach wherein the transistor is built on a semiconductor substrate. However, the wafer transfer process creates additional process complexity, as additional device processing may be done post transfer (such as emitter patterning) in addition to the layer transfer itself.

It may be desirable, therefore, to produce HBTs and III-V HEMTs by a monolithic approach, i.e. by fabricating the devices on a base substrate and without applying wafer transfer, while at the same time increasing significantly the thermal conductivity from the device towards the base substrate.

Patent publication document US2010/237434 discloses a method for creating a buried low electrical resistance region underneath a semiconductor device processed on a silicon substrate. The low resistance region is obtained by etching a thin buried SiGe layer and removing the etched material through an opening, followed by depositing a metal to fill the thin cavity created by the removal of the SiGe. The SiGe layer is not confined to a specific area, so that it is difficult to control the dimensions of the buried conductive region. The conductive region is furthermore thin, so that its effect on heat removal from the device is minimal. Enlarging the volume requires etching the silicon substrate which is however an uncontrolled process so that it is impossible to obtain a thermally conductive volume of significant dimensions without losing control over the dimensions.

### SUMMARY

Example embodiments relate to methods and to semiconductor components in accordance with the appended claims. According to example methods, a laterally isolated mesa structure is produced on a semiconductor substrate, with active layers of a semiconductor device integrated in an upper portion of the mesa structure. One or more openings are formed in the dielectric material that is isolating the mesa structures on the lateral sides thereof, and a bottom portion of the mesa structure and/or a portion of the dielectric material in a region directly adjacent to the bottom portion of the mesa structure is removed relative to the substrate and relative to the active layers. A cavity is thereby formed that is subsequently filled with a highly thermally conductive material, thereby creating a volume of high thermal conductivity configured to remove heat from the device to the substrate. In the context of the present disclosure, the term “high thermal conductivity” refers to materials having thermal conductivity between 50 and 500 W/mK. Example materials may include metals, such as tungsten or ruthenium.

The method enables improved heat removal from the active device layers while producing the device in a monolithic approach on a substrate, i.e. without requiring substrate transfer steps during the production process of the device. This may be beneficial in the case of high-power devices such as heterojunction bipolar transistors and high-electron-mobility transistors comprising active layers formed of III-V materials.

The bottom portion of the mesa structure is by definition part of the mesa structure. It is therefore a well-defined region underneath the active device, delimited on all sides. The cavity is created by one of the following actions:
removing the bottom portion selectively with respect to all materials surrounding the bottom portion, i.e. relative to the semiconductor substrate, to the active layers of the device and with respect to the dielectric material isolating the mesa structure laterally,
removing both the bottom portion and a volume of dielectric material directly adjacent thereto, wherein the dielectric material is also removed selectively with respect to the substrate,
removing only the volume of dielectric material directly adjacent to the bottom portion, selectively with respect to the substrate,

The fact that the bottom portion is confined to a well-defined region and that the removal of the bottom portion takes place selectively implies that the cavity created by removing the bottom portion also has well-defined dimensions. Hence, when filling the cavity with highly thermally conductive material, a thermally conductive volume is obtained having well-defined dimensions. This enables the creation of a thick thermally conductive volume under the active device. Removal of the dielectric material also takes place selectively with respect to the substrate, so the thickness of the thermally conductive volume obtained from removing dielectric material is equally well-defined. This is contrary to document US2010/237434 where it is required to etch the substrate in order to increase the dimensions of the buried conductive region.

In particular embodiments, the bottom portion of the mesa structure may include a buffer layer of a III-V device processed on a substrate that is lattice mismatched with respect to the III-V material, or a bottom portion of a device processed from a nanoridge structure.

Throughout this description, the expression “removing a first layer or material by etching relative to a second layer or material” includes two variants. Firstly the expression can refer to applying a selective etch recipe, i.e. wherein the first material is fully removed while the second material is not removed or removed partially in accordance with an etch selectivity rate (e.g. 95%). Secondly, the expression can refer to removing the first material while the second material is protected by an etch stop layer, i.e. etching stops on the etch stop layer. The etch stop layer may thereafter be removed selectively with respect to the second material by another etch recipe or it may remain in place.

Example embodiments are related to a semiconductor processing method comprising the steps of:
providing a substrate formed of a first semiconductor material,
producing a mesa structure on the substrate and in direct contact with the substrate, wherein the mesa structure is isolated on all lateral sides by dielectric material, and wherein active layers of a semiconductor device are integrated in an upper portion of the mesa structure (“upper portion” meaning: lying on the opposite side of the substrate),
producing one or more openings through the dielectric material. The openings are made only through the dielectric material, i.e. without passing through the active layers,
removing a bottom portion of the mesa structure through the one or more openings and/or removing the dielectric material in a region directly adjacent to the bottom portion of the mesa structure, by one or more etching steps configured to remove material relative to the substrate and relative to the active layers integrated in the upper portion, thereby forming a cavity,
filling the cavity through the one or more openings with a material of high thermal conductivity, thereby obtaining a thermally conductive volume configured to remove heat produced in one or more of the active layers of the device, towards the substrate.

According to an embodiment, the mesa structure is formed of semiconductor materials which exhibit a lattice mismatch relative to the first semiconductor material, for example III-V materials grown by epitaxial growth on a silicon substrate. The lattice mismatch implies that the bottom portion of the mesa structure has a significant thickness, for example, on the order of 1 to 10 μm in the case of a III-V buffer layer grown on a crystalline Si substrate. Replacing such a bottom portion by a highly thermally conductive material thereby enables creating a thick thermally conductive volume underneath the device.

According to an embodiment, the semiconductor materials exhibiting a mismatch are III-V semiconductor materials.

According to an embodiment, the first semiconductor material is crystalline silicon. Other choices for the first semiconductor material are also possible, for example GaAs.

According to an embodiment, wherein the bottom portion of the mesa structure comprises at least part of a buffer layer formed on the substrate for compensating a lattice mismatch between the first semiconductor material and one or more semiconductor materials applied in the active device layers.

According to an embodiment, the dielectric material is realised in the form of a first dielectric-filled trench that surrounds the mesa structure on all lateral sides and a second dielectric-filled trench of lower depth than the first trench and positioned inside the first trench.

According to an embodiment, producing the mesa structure comprises forming a nanoridge structure extending in a longitudinal direction and forming a first layer obtained by epitaxial growth of a second semiconductor material in a first trench extending in the longitudinal direction and passing through a dielectric support layer formed on the substrate, and subsequently in a second trench wider than the first trench and aligned thereto, the second trench passing through a dielectric template layer formed on the support layer, wherein:
the second semiconductor material is lattice mismatched relative to the first semiconductor material,
when growing above the first trench, the first layer expands to the width of the second trench,
the aspect ratio of the first trench is configured so that the material growing above the first trench is essentially defect-free,
further semiconductor layers may be grown on the first layer to thereby form the nanoridge structure,
the production of the mesa structure includes isolating a longitudinally arranged portion of the nanoridge structure so that the mesa structure comprises a portion of the first layer at the bottom of the mesa structure,
in the longitudinal direction, the mesa structure is isolated on both sides by an additional dielectric layer, and in the direction perpendicular thereto the mesa structure is isolated on both sides by the support layer, the template layer, and the additional dielectric layer, so that the dielectric material isolating the mesa structure on all sides includes the materials of the additional dielectric layer, the support layer and the template layer,
wherein the bottom portion of the mesa structure comprises at least the portion of the first layer at the bottom of the mesa structure.

According to an embodiment, the one or more openings are produced on one or both sides of the mesa structure along the longitudinal direction, wherein the one or more openings pass through the additional dielectric layer.

According to an embodiment, an etch stop layer is produced on the sidewalls of the second trench in the template layer, wherein the bottom portion of the mesa-structure is removed and wherein in addition to the removal of the bottom portion of the mesa-structure, portions of the support layer on both sides of the first trench are removed by etching while the etch stop layer protects the material of the template layer, thereby widening the cavity at the base thereof.

According to an embodiment, the one or more openings are produced on one side of the mesa structure in a direction perpendicular to the longitudinal direction, wherein the one or more openings pass through the additional dielectric layer and at least partially through the template layer and wherein the etching steps include at least etching the material of the template layer and the support layer selectively with respect to the additional dielectric layer and with respect to the substrate.

According to an embodiment, the mesa structure is one of a pair of adjacent mesa structures produced from a pair of mutually parallel nanoridges, wherein the one or more openings are made in the spacing between the mesa structures, and wherein the cavity is common to both mesa structures.

According to an embodiment, one opening is formed between the mesa structures, wherein the width of the opening is aligned to the spacing between the mesa structures.

According to an embodiment, the semiconductor device is a heterojunction bipolar transistor (HBT) or a high-electron-mobility transistor (HEMT).

Example embodiments also relate to a semiconductor component comprising a semiconductor substrate, a front end of line portion comprising active semiconductor devices on the substrate, and a back end of line portion on the FEOL portion, wherein at least one of the semiconductor devices comprises active layers which are integrated in an upper portion of a mesa structure that is in direct contact with the substrate, and wherein the mesa structure is isolated on all lateral sides by dielectric material, characterized in that the mesa structure comprises a thermally conductive volume extending at least partially between the active layers and the substrate or adjacent to a bottom portion of the mesa structure.

According to some embodiments, the at least one semiconductor device is a heterojunction bipolar transistor (HBT) or a high-electron-mobility transistor (HEMT).

### BRIEF DESCRIPTION OF THE DRAWINGS

FIG. 1A illustrates a method applied to a HEMT device, according to example embodiments.

FIG. 1B illustrates a method applied to a HEMT device, according to example embodiments.

FIG. 2A illustrates a method applied to a HEMT device, according to example embodiments.

FIG. 2B illustrates a method applied to a HEMT device, according to example embodiments.

FIG. 3 illustrates a method applied to a HEMT device, according to example embodiments.

FIG. 4 illustrates a method applied to a HEMT device, according to example embodiments.

FIG. 5 illustrates a method applied to a HEMT device, according to example embodiments.

FIG. 6A illustrates a method applied to a HBT device produced on a nanoridge structure, according to example embodiments.

FIG. 6B illustrates a method applied to a HBT device produced on a nanoridge structure, according to example embodiments.

FIG. 6C illustrates a method applied to a HBT device produced on a nanoridge structure, according to example embodiments.

FIG. 7A illustrates a method applied to a HBT device produced on a nanoridge structure, according to example embodiments.

FIG. 7B illustrates a method applied to a HBT device produced on a nanoridge structure, according to example embodiments.

FIG. 7C illustrates a method applied to a HBT device produced on a nanoridge structure, according to example embodiments.

FIG. 8A illustrates a method applied to a HBT device produced on a nanoridge structure, according to example embodiments.

FIG. 8B illustrates a method applied to a HBT device produced on a nanoridge structure, according to example embodiments.

FIG. 9A illustrates a method applied to a HBT device produced on a nanoridge structure, according to example embodiments.

FIG. 9B illustrates a method applied to a HBT device produced on a nanoridge structure, according to example embodiments.

FIG. 10 illustrates a variant of the method of FIGS. 6-9, according to example embodiments.

FIG. 11 illustrates a variant of the method of FIGS. 6-9, according to example embodiments.

FIG. 12A illustrates a method, applied to a pair of adjacent HBT fingers produced on adjacent nanoridge structures, according to example embodiments.

FIG. 12B illustrates a method, applied to a pair of adjacent HBT fingers produced on adjacent nanoridge structures, according to example embodiments.

FIG. 13A illustrates a method, applied to a pair of adjacent HBT fingers produced on adjacent nanoridge structures, according to example embodiments.

FIG. 13B illustrates a method, applied to a pair of adjacent HBT fingers produced on adjacent nanoridge structures, according to example embodiments.

FIG. 14 illustrates a method, applied to a pair of adjacent HBT fingers produced on adjacent nanoridge structures, according to example embodiments.

FIG. 15 illustrates a method, applied to a pair of adjacent HBT fingers produced on adjacent nanoridge structures, according to example embodiments.

FIG. 16 illustrates a method, applied to a pair of adjacent HBT fingers produced on adjacent nanoridge structures, according to example embodiments.

FIG. 17 illustrates a method, applied to a pair of adjacent HBT fingers produced on adjacent nanoridge structures, according to example embodiments.

FIG. 18 illustrates a method, applied to a pair of adjacent HBT fingers produced on adjacent nanoridge structures, according to example embodiments.

FIG. 19 illustrates a method, applied to a pair of adjacent HBT fingers produced on adjacent nanoridge structures, according to example embodiments.

FIG. 20 illustrates a method, applied to a pair of adjacent HBT fingers produced on adjacent nanoridge structures, according to example embodiments.

FIG. 21 illustrates a method, applied to a pair of adjacent HBT fingers produced on adjacent nanoridge structures, according to example embodiments.

FIG. 22 illustrates a method applied on a pair of nanoridge-based HBT fingers or on a single nanoridge-based HBT device, according to example embodiments.

FIG. 23 illustrates a method applied on a pair of nanoridge-based HBT fingers or on a single nanoridge-based HBT device, according to example embodiments.

FIG. 24 illustrates a method, according to example embodiments.

FIG. 25 illustrates a method, according to example embodiments.

FIG. 26 illustrates a method, according to example embodiments.

FIG. 27 illustrates a method applied to a nanoridge-based HEMT device, according to example embodiments.

### DETAILED DESCRIPTION

In the following detailed description, a number of embodiments of the method will be described. All references to specific materials and dimensions are cited only by way of example and are not limiting the scope of the present disclosure.

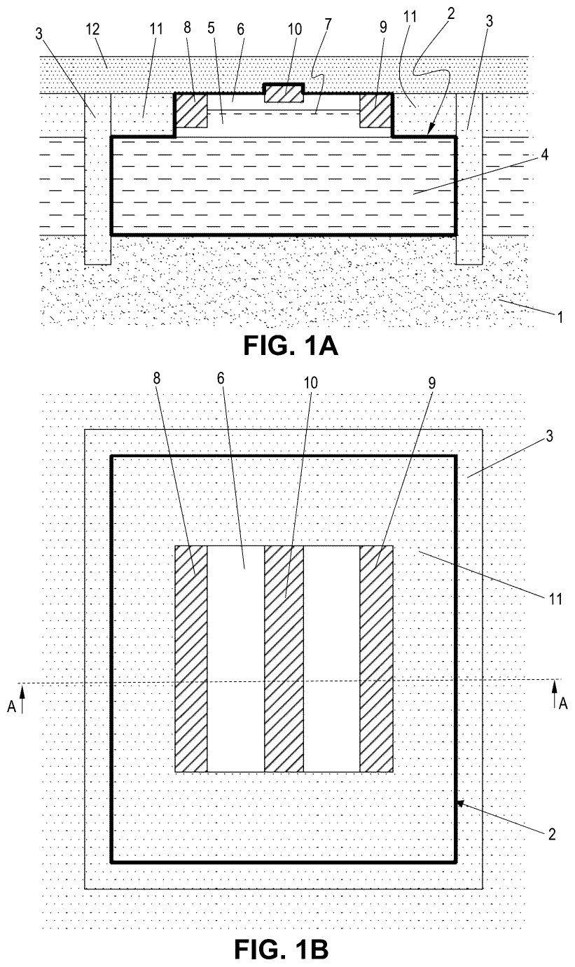

FIGS. 1A and 1B show two section views of a III-V HEMT device processed on a silicon substrate 1, for example on a 300 mm crystalline silicon process wafer 1. The image is not a drawing on scale of a realistic device, and is intended only to indicate a number of layers and components that are of relevance to the disclosure. The HEMT is part of a mesa-structure 2 indicated by the bold line in the section views in FIGS. 1A and 1B. The mesa-structure 2 is isolated on all sides from the remainder of the Si wafer by a deep trench 3 filled with a dielectric material, and by a shallow trench 11 lying inside the deep trench 3 and equally filled with a dielectric material. The bottom portion of the mesa-structure 2 is a thick buffer layer 4 in direct contact with the wafer 1. On the buffer layer 4, active layers of the HEMT are formed, namely a channel layer 5 and a barrier layer 6. The active layers are formed of III-V compound semiconductor materials.

In some cases, a GaAs channel layer 5 may be combined with a doped AlGaAs barrier layer 6 on top. The doping level of the barrier layer is configured to create a so-called 2DEG (2-dimensional electron gas) 7 in the channel layer 5, at the interface between the channel layer 5 and the barrier layer 6, exhibiting high electron mobility in the plane of the 2DEG. Source and drain electrodes 8 and 9 are in electrical contact with the 2DEG 7, and a gate electrode 10 is produced between the source and drain electrodes. Further examples of III—As based HEMTs in terms of the materials of the barrier and channel layers can be, AlGaAs/InGaAs, InGaP/InGaAs, InAlAs/InGaAs, InAlAs/InP. The shallow and deep dielectric-filled trenches 11 and 3 isolate the HEMT from other devices processed on the wafer 1. The dielectric material in the trenches may be SiO₂ for example. On top of the mesa structure 2 is a layer 12 of dielectric material which may be referred to as a pre-metal dielectric. It may be SiO₂ or a low k material. Layer 12 is transparent in the plane view in FIG. 1B in order to visualize the various components.

The main purpose of the buffer layer 4 is to alleviate the effects of the mismatch between the lattice constants of the substrate 1 and the active layers of the transistor. The buffer layer 4 is thick, for example in the order of 1 to 10 □m, compared to the active device layers 5,6 which are usually in the order of tens of nanometers in thickness. The buffer layer 4 is often produced from alloy materials which have low thermal conductivity. For III-As based HEMTs, the buffer can be formed of GaAs, InP, AlAs or their alloys such as InGaAs, InAlAs, InGaP, etc.

Many ways exist of bringing the mesa structure 2 into practice, in terms of the materials chosen, thicknesses of the various layers and geometrical configuration of the electrodes. Methods for producing a HEMT according to any of these configurations may be straightforward and, therefore, may not be included in this description. Example embodiments deal with a number of additional steps aimed at lowering the thermal resistance (improving the heat removal) from the device to the substrate. These steps are performed before via connections are produced through the pre-metal dielectric layer 12 for connecting the electrodes of the HEMT to electrical conductors embedded in further dielectric layers of a back end of line (BEOL) interconnect structure that is built layer by layer on top of the front end of line (FEOL) layer which comprises the HEMT and other devices processed on the Si wafer 1.

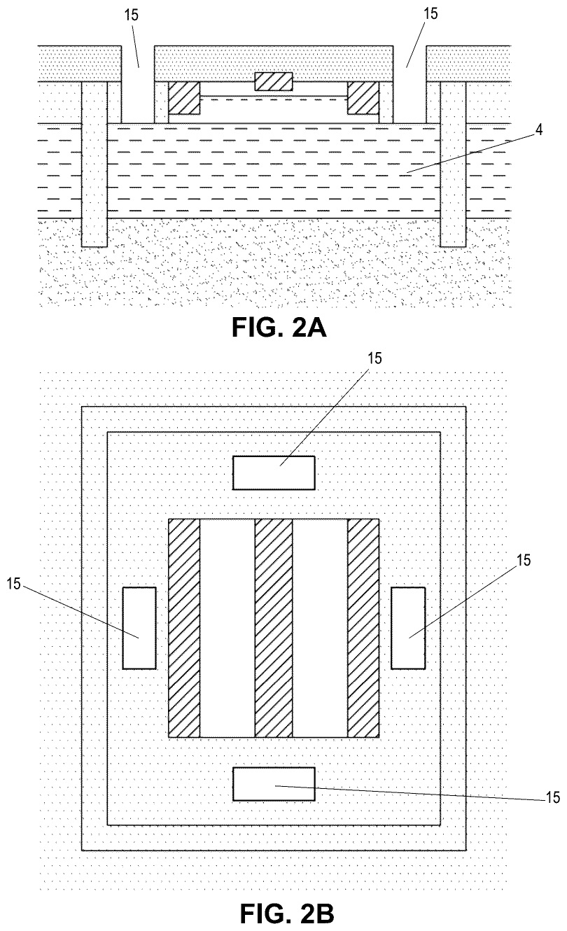

As illustrated in FIGS. 2A and 2B, via openings 15 are produced through the pre-metal dielectric layer 12 and the STI region 11. This may be done by standard lithography and etch steps. The etch process stops on the buffer layer 4 but may also continue to some degree into the buffer layer.

Following this and as illustrated in FIG. 3, the buffer layer 4 is removed relative to the Si wafer 1, the dielectric material in the deep trenches 3 and in the shallow trenches 11, and with respect to the active layers of the HEMT. This may be done by applying one or more wet etch recipes. The etchant dissolves the buffer layer materials which are then removed through the via openings 15. Suitable selective etch recipes may be straightforward for the selective removal of at least the above-named materials, which may be applied as constituent materials of a buffer layer used in HEMT designs, wherein the etch recipes are selective with respect to the substrate 1 and with respect to the dielectric materials in the trenches 3 and 11. In some embodiments, an etch stop layer may be included between the buffer layer and the channel layer, to avoid removing the channel layer fully or partially.

The etch process creates a cavity 16 located directly adjacent the wafer 1 and between the HEMT device and the wafer 1. This cavity 16 is subsequently filled with a highly thermally conductive material through the openings 15, which may for example be done by ALD or CVD (Chemical Vapor Deposition). The highly thermally conductive material may be metal, for example copper, tungsten, or ruthenium. This step may be preceded by producing a metal seed layer on at least part of the inner surface of the cavity 16.

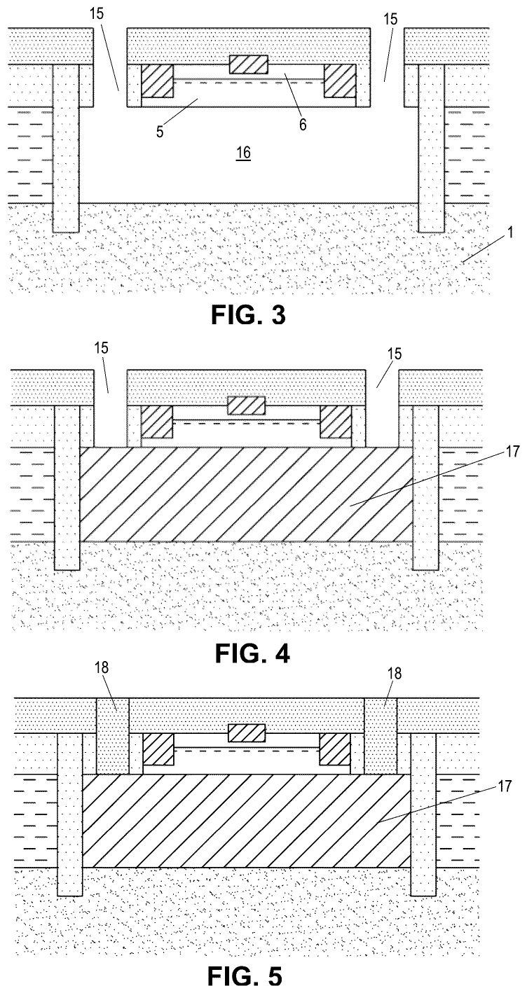

The metal filling process ends when the cavity 16 is filled with metal, as illustrated in FIG. 4, thereby obtaining a volume 17 of high thermal conductivity. In the embodiment shown, no metal is formed in the via openings 15.

As the bottom portion of the mesa structure 2 is the thick buffer layer 4, the volume 17 is also thick, for example, 1 μm or more. The bottom portion 4 is removed selectively with respect to all the layers above and below the bottom portion, and with respect to the dielectric material that isolates the bottom portion, i.e. the etch process stops on the silicon substrate 1 at the bottom, on the channel layer 5 at the top and on the dielectric-filled trenches 3 and 11 laterally. This approach enables the creation of a thick thermally conductive volume of well-defined dimensions.

The next step is illustrated in FIG. 5 and includes filling the via openings 15 with a dielectric 18. In some embodiments, the dielectric 18 may be the same material as the pre-metal dielectric layer 12. The upper surface is then planarized, resulting in the image shown in FIG. 5. From this point on, straightforward steps may be performed for producing via connections to the electrodes of the HEMT and for producing the multiple layers forming the BEOL structure.

According to another embodiment, the metal filling process continues to fill the openings 15 with metal. These metal-filled openings may be used as conductors for realizing an electrical connection to the volume 17, so that this volume is not in an electrically floating state during operation of the HEMT.

The metal-filled cavity 17 represents a volume having high thermal conductivity that extends between the substrate 1 and the active layers 5,6 of the HEMT and will thus be able to efficiently evacuate heat produced by the HEMT towards the wafer 1 when the HEMT is in operation.

It is a characteristic of some embodiments that the highly thermally conductive volume is obtained in a so-called monolithic production process, i.e. a production process of semiconductor components such as IC chips on a substrate, wherein the substrate 1 remains the supporting member of the multiple active devices of the component throughout the FEOL and BEOL stages of the production process. This means that no transfer of fully or partially processed active devices to another substrate takes place during the production process.

In some embodiments, the material used for filling the cavity 16 may be highly thermally conductive so as to enhance heat removal from the semiconductor device. Metals are therefore prime candidates for this material.

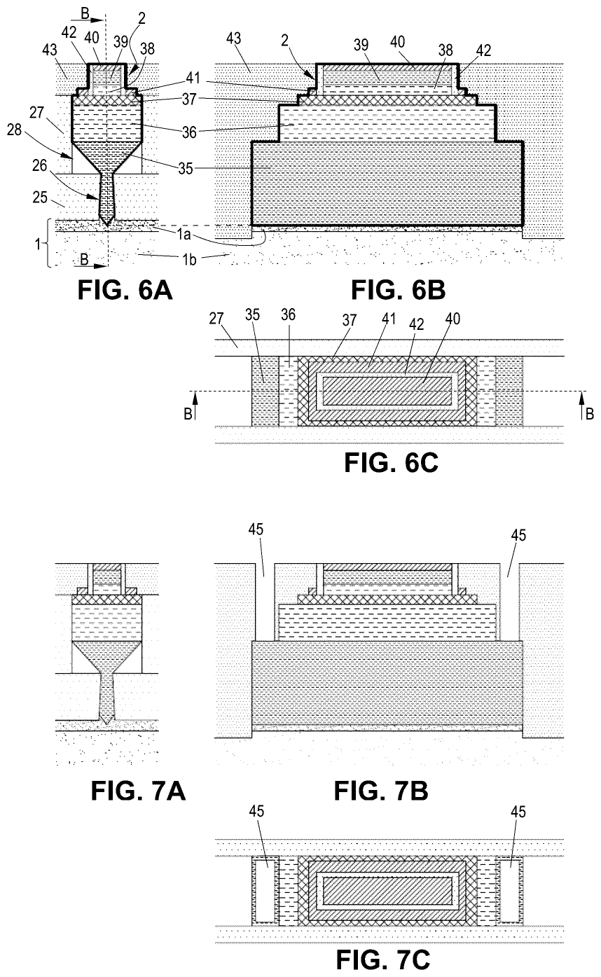

Another device to which the disclosure is applicable is shown in FIGS. 6A-6C, showing views in three orthogonal directions of a heterojunction bipolar transistor (HBT) produced on a nanoridge structure. Nanoridge engineering (NRE) technology may be straightforward and described, for example, in patent publication document EP3789519. According to some embodiments, the technique involves the growing of III-V material in narrow nano-sized grooves having silicon or another material that is lattice mismatched with respect to the III-V material at the bottom of the grooves. The material grows into nano-ridges which protrude out of the grooves. Defects are trapped in the grooves by aspect ratio trapping (ART), and the upper layers of the nano-ridges are essentially defect-free. NRE thereby enables the growth of III-V materials on lattice mismatched substrates without requiring a thick buffer layer.

FIGS. 6A-6C illustrate the HBT in two orthogonal section views and a plane view. The substrate 1 is a Si process wafer. For producing HBTs or HEMTs for RF applications, a nominal resistivity or high resistivity (>100 Ω·cm) Si wafer may be used. As seen in FIG. 6A, a dielectric layer 25 lies directly on the wafer surface, and a narrow trench 26 cuts through the dielectric layer 25. The bottom of the trench is Si that has been anisotropically etched, i.e. according to the crystal planes of the crystalline Si, resulting in a V-shaped bottom shape. This can be done by producing a narrow Si fin, thereafter depositing the dielectric layer 25, planarizing the latter, and selectively etching the material of the fin by anisotropic etching.

According to the illustrated embodiment, the Si fin is initially produced in a top layer 1a of the substrate. In example embodiments described hereafter of an npn HBT produced on Si, the top layer 1a is n-doped and obtained by a doping implant on a p-Si process wafer 1a. The n-doping is used to create a p-n junction for low leakage from the HBT to the substrate. Example embodiments are however not limited to the use of Si substrates. Other substrates may be used, such as Ge, GaAs, or InP substrates.

A second dielectric layer 27 is produced on the planarized surface, and a second trench 28 is produced therein, aligned to and potentially coaxial with the narrow trench 26, and significantly wider than the narrow trench 26. The second dielectric layer 27 is hereafter referred to as a template layer, while the first dielectric layer 25 is hereafter referred to as a support layer.

III-V material 35 is then grown by epitaxial growth in the narrow trench 26, which may be done by metal organic vapour phase epitaxy (MOVPE) in a reactor suitable for applying this growth technique. The III-V material exhibits a lattice mismatch with respect to the Si lattice. The width and depth of the narrow trench 26 are however chosen such that growth defects are trapped in the trench 26, and the material growing out of the trench 26 is essentially defect-free. Once the material reaches the top of the narrow trench 26, it expands to a width higher than the narrow trench width, until the widening is stopped by the sidewalls of the wider trench 28 in the template layer 27. III-V material grown directly on the Si wafer is therefore essentially defect-free at its upper surface, where it has the width of the template trench 28, which may be in the order of 1 micrometre for example.

An HBT as illustrated in FIGS. 6A-6C is produced from a nano-ridge structure which may be several millimetres long, and which is formed by growing further III-V layers on the layer that is grown directly on the Si and that widens to the width of the wide trench 28. A number of the upper layers may then be processed by straightforward method steps to arrive at the HBT structure as illustrated. The resulting HBT is again part of a mesa-structure 2 delineated by the thick line in FIGS. 6A and 6B.

The example device shown is an npn HBT comprising the following parts: a subcollector 35, a collector 36, a base 37, an emitter 38, an emitter contact layer 39, an emitter electrode 40, a base electrode 41. The subcollector 35 and the emitter contact layer 39 are high n-doped regions. The collector 36 and the emitter 38 are low n-doped regions. The base 37 is high p-doped. The electrodes are formed of metal. The terms “high or low doped” refer to higher or lower doping levels of a given layer. In some embodiments, doping levels may be obtained by adding measured concentrations of dopants to the MOVPE reactor during the growth process.

The subcollector 35 includes the III-V material grown in the narrow trench 26 on the lattice-mismatched Si at the bottom the narrow trench. The part of subcollector 35 which grows inside the trench 26 may therefore be regarded in the present context as a buffer layer as it fulfils the function of compensating the lattice mismatch, even though this is achieved in a different way than in the case of a blanket buffer layer 4 as described with reference to FIGS. 1-5.

Examples of possibly applicable materials are the following: n-doped InGaAs, InAlAs, InGaP or InP for the subcollector 35, n-doped InP, InGaP, or InAlAs for the collector 36, n-doped InP or InGaP for the emitter 38 and InGaAs or InAs for the emitter contact layer 39, with high or low doping levels, and p-doped InGaAs or GaAsSb for the base 37. Suitable doping levels and thicknesses of the various layers may be used.

The emitter 38 and emitter contact layer 39 are laterally isolated from the base electrode 41 by a dielectric spacer 42. Along the length direction of the nano-ridge (as seen in FIG. 6B), the subcollector 35 is longer than the collector 36, and the collector 36 is longer than the base 37, which is in turn longer than the emitter/emitter contact stack 38/39. The mesa structure 2 is isolated from other devices lying in the longitudinal direction of the nanoridge by an additional dielectric layer 43, that is planarized to a common level with the upper surface of the emitter electrode 40.

The “additional dielectric layer” 43 is represented as a uniform layer but it may include different parts and materials. For example it may include a deep trench like the trench 3 shown in FIG. 1A around a group of adjacent HBT fingers (see further), and it may further comprise pre-metal dielectric material deposited on the active layers of the HBT device and planarized in preparation of the further processing of the BEOL portion.

In the direction perpendicular thereto, the mesa structure 2 is isolated by the same dielectric layer 43, and further by the opposite portions of the template layer 27 on either side of the wide trench 28 produced in the template layer, and by the opposite portions of the support layer 25 on either side of the narrow trench 26 in the support layer 25. The support layer 25 and the template layer 27 can be SiO₂. The dielectric layer 43 may be comprise SiO₂ or a low k dielectric layer. In the plane view in FIG. 6C, the dielectric layer 43 is transparent in order to visualize the underlying parts.

According to the embodiment shown in the drawings, the subcollector 35 is a portion of the first layer of the nanoridge, i.e. the layer that is grown directly on the Si at the bottom of the narrow trench 26 and that grows out of the narrow trench to the width of the wider trench 28. The portion is isolated on both sides by the dielectric layer 43. According to other embodiments, the subcollector 35 could comprise one or more additional layers on the portion of the directly grown nanoridge layer.

According to some techniques, the stage shown in FIGS. 6A-6C is followed by the production of a further pre-metal dielectric on the planarized upper surface, and by etching via openings through the pre-metal dielectric towards the subcollector 35, the base 37 and emitter contact layer 39, and filling these openings with metal for connecting these parts of the HBT to the BEOL portion that is thereafter built layer by layer on the planarized surface.

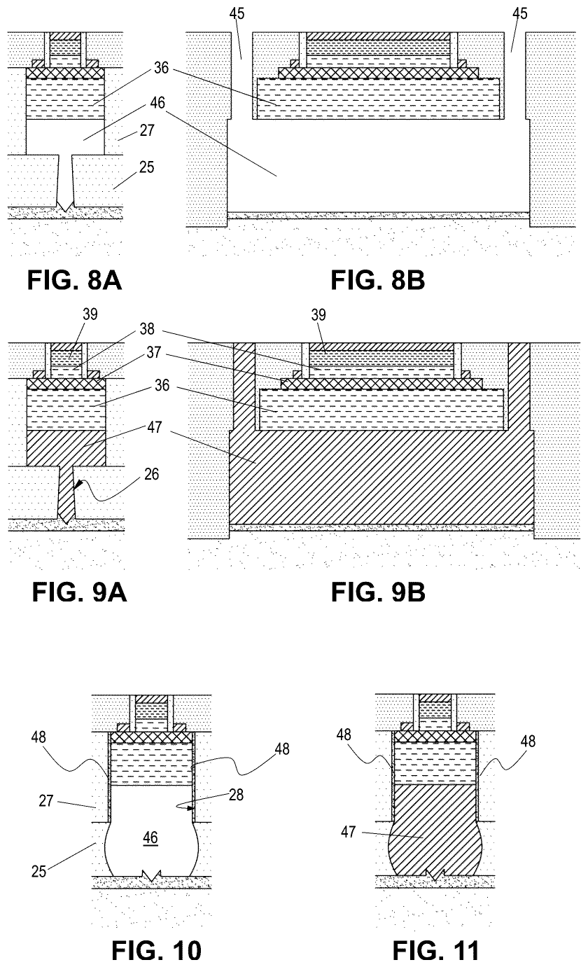

According to some embodiments, a number of additional steps is performed prior to making these electrical connections and building the BEOL portion. A first nanoridge-based embodiment is illustrated in FIGS. 7-10. As shown in FIGS. 7A-7C, via openings 45 are produced through the dielectric layer 43, on both sides of the collector 36, landing on the subcollector 35. Reference is then made to FIGS. 8A and 8B. A wet etchant is supplied through the via openings 45, and the subcollector 35 is removed relative to the collector 36 and relative to the dielectric material of the support layer 25 and the template layer 27. Etch recipes with sufficient selectivity are available for removing most III-V materials relative to dielectric materials and to other III-V material, for example for removing InP relative to SiO₂ and vice-versa. When the material of the subcollector 35 is different from the material of the collector 36, a selective etch recipe can be used to remove the subcollector 35 relative to the collector 36. Often however, the same material is used for the collector and the subcollector. In this case, an etch stop layer may be applied as the top layer of the subcollector 35. For example, the subcollector 35 may comprise a bottom portion directly on the Si in the narrow trench 26 and widening to the width of the wide trench 28, and on the bottom portion, the subcollector 35 may further comprise an additional thin layer of III-V material of a different type than the material of the bottom portion. For example, a thin highly n-doped InGaAs layer could be grown on the highly n-doped InP bottom part during the production of the nanoridge structure. This thin layer stops the wet etch process when the InP bottom portion of the subcollector is removed. In another example, the sub-collector 35 may include InGaAs grown on Si and the collector 36 may include InP, InGaP, or InAlAs and the InGaAs of the subcollector 35 may be selectively etched with respect to the collector materials. After the removal of the subcollector 35 (possibly with the exception of a thin etch stop layer in some cases), a cavity 46 is created underneath the HBT, as shown in FIGS. 8A and 8B. The cavity has well-defined dimensions, given that the subcollector 35 is removed selectively with respect to all surrounding materials.

This is then followed by depositing a highly thermally conductive material, in the cavity 46, which can be done by ALD or CVD. In this case, the material may be electrically conductive, so it may be a metal like, but not limited to, copper, tungsten, or ruthenium. This may be preceded by the formation of a metal seed layer on the inner surface of the cavity 46. As shown in FIGS. 9A and 9B, a volume 47 of high thermal conductivity is thereby obtained. In the case shown, the metal also fills the via openings 45, so that when the upper surface is planarized as shown, the BEOL part can be produced thereon, including electrical connections to the collector, base and emitter of the HBT. The metal volume 47 thereby also plays the part of contact electrode to the collector 36.

The metal-filled cavity 47 again represents a volume having high thermal conductivity towards the substrate 1, enabling more efficient heat removal from the HBT when the latter is operational in a component comprising the HBT and other devices produced on the substrate 1 by a monolithic process. However, the narrow metal-filled trench 26 may still geometrically constrict the heat flow to some degree. Another embodiment is illustrated in FIGS. 10 and 11. An etch stop layer 48 has been provided on the sidewalls of the wider trench 28 in the template layer 27. This may for example be a thin SiN layer. The presence of this etch stop layer 48 allows to remove also a portion of the support layer 25 without attacking the template layer 27, so that the cavity 46 is wider at the base compared to the case shown in FIG. 8A. Filling the cavity with metal, as shown in FIG. 11, this results in a larger metal volume 47 and hence to a better thermal conductivity.

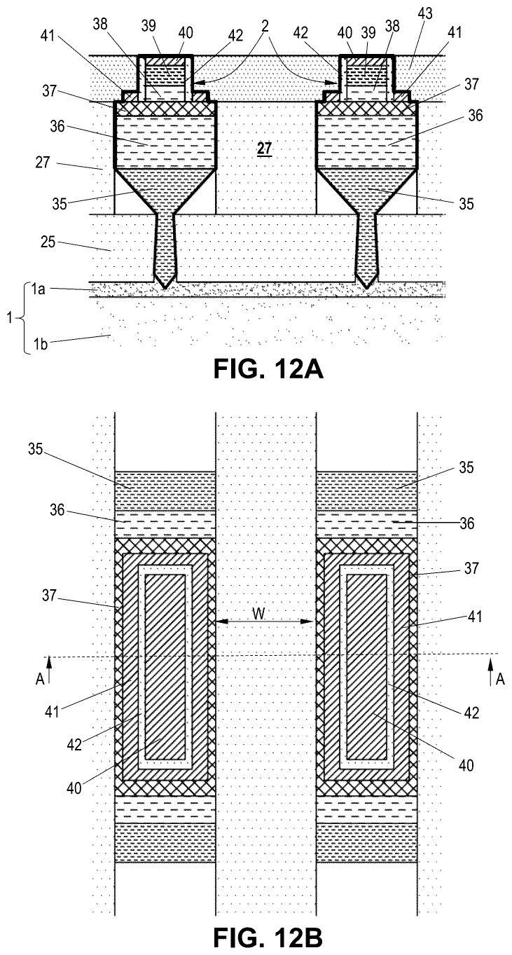

Another embodiment is illustrated in FIGS. 12-21. FIGS. 12A and 12B show two HBT structures produced side by side on two adjacent nanoridge structures and intended to form together a single HBT by interconnecting the respective electrodes. For this reason, the adjacent structures are hereafter referred to as HBT fingers. Nanoridge structures are usually produced in large numbers of mutually parallel structures, to enable processing multi-finger devices thereon. Some embodiments make use of the spacing between two adjacent nanoridges to realise a highly thermally conductive volume underneath the two adjacent fingers. The width W of the spacing may be in the same order of magnitude as the width of the nanoridges. The same numerical references are applied for indicating the constituent parts of the adjacent HBTs, each of which is part of a mesa structure 2 as defined above.

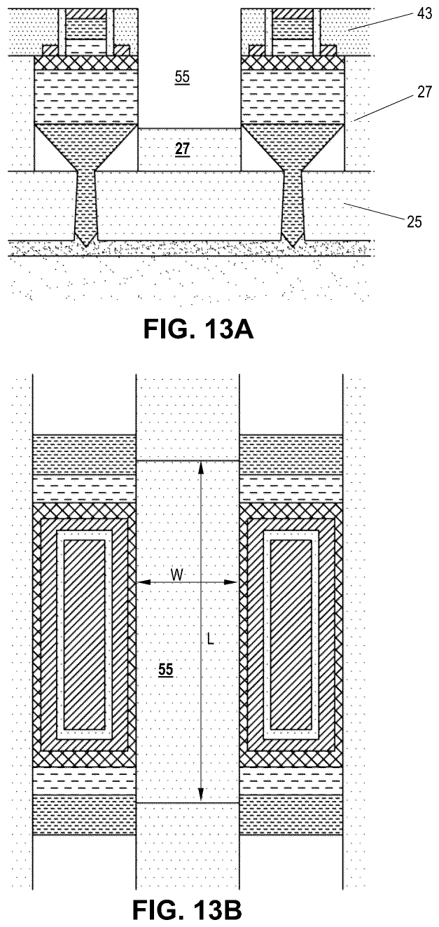

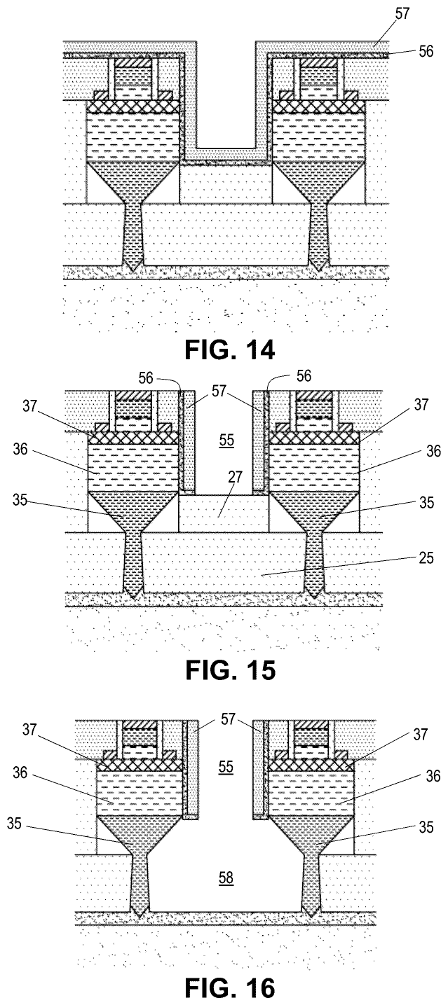

As illustrated in FIGS. 13A and 13B, an opening 55 is etched through the dielectric layer 43 and partially through the template layer 27. The opening 55 is aligned to the spacing between the HBT fingers, i.e. the opening has the same width Was the spacing. The length L of the opening 55 is of the same order of magnitude as the length of the mesa structures 2. With reference to FIG. 14, an etch stop layer 56 and a further dielectric layer 57 are produced conformally on the sidewalls and the bottom of the opening 55, and on the upper planarized surface of the dielectric layer 43. The etch stop layer 56 could be formed for example of HfO₂ or Al₂O₃ and may be applied by ALD. The material of dielectric layer 57 is chosen so that the material of the template layer 27 and the support layer 25 can be removed with high selectivity by wet etching, relative to this layer 57. A dry etch process is then applied, removing the dielectric layer 57 on the horizontal parts and maintaining it on the sidewalls of the opening 55. This dry etch process is stopped by the etch stop layer 56, which is thereafter removed as shown in FIG. 15, by another dry etch recipe that removes the etch stop layer 56 selectively with respect to the underlying materials. In an alternative approach, the etch stop layer 56 is not applied, and the dry etch for removing layer 57 on the horizontal parts is a timed etch process.

Thereafter, the material of the template layer 27 and of the support layer 25 is removed in the area exposed by the opening 55, wherein the area lies between the subcollectors 35 of the HBTs. In the length direction of the nanoridges, wherein the area is delimited by delimiting regions formed of the dielectric material of layer 43. In these delimiting regions in the longitudinal direction of the HBT fingers, wherein the dielectric material is chosen so that the template and support layer materials are removable selectively with respect to the dielectric material of layer 43. One example of a suitable material is Si₃N₄. The removal of these materials creates a cavity 58 as illustrated in FIG. 16, while the collectors 36 and bases 37 of the HBTs are protected by the dielectric layer 57 on the sidewalls of the opening 55.

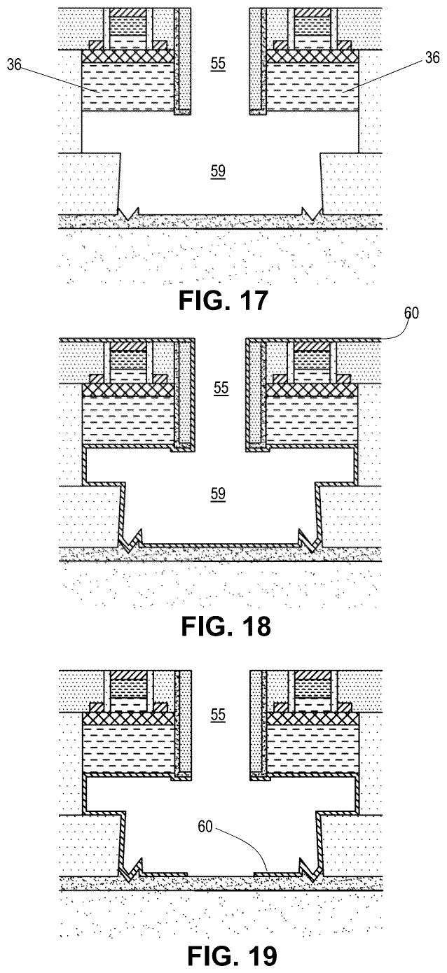

With reference to FIG. 17, another wet etch recipe is applied which removes the subcollector layers 35 of both HBTs relative to the respective collectors 36 thereof. Depending on the materials used for the various layers, some embodiments may provide an etch stop layer as the top layer of the subcollectors 35, as described above, in order to ensure that the collectors 36 are not attacked by this etch process. An enlarged cavity 59 is thereby obtained.

The next step may be applied also in the embodiments described previously, but here it is shown explicitly in FIG. 18. A metal seed layer 60 is deposited conformally on the exposed inner surface of the enlarged cavity 59 and on the upper planarized surface of the dielectric layer 43. This may be done by ALD. The metal seed layer 60 is suitable for depositing thereon a metal by ALD or CVD.

As shown in FIG. 19, an anisotropic etch process with some degree of lateral etching may be applied, removing the seed layer 60 in areas which are visible in the direction perpendicular to the upper planarized surface. This removes the seed layer 60 from the upper surface, from the sidewalls of the opening 55, and from a central area of the bottom of the enlarged cavity 59.

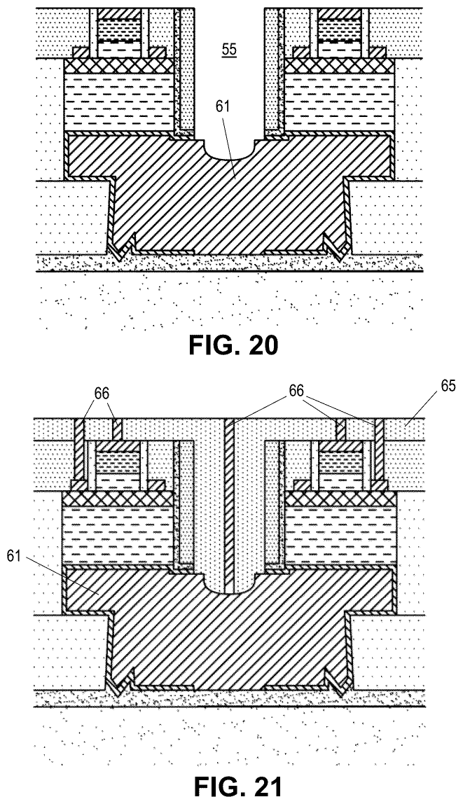

Thereafter and with reference to FIG. 20, a metal is deposited by selective ALD or CVD (for example tungsten CVD), so that it grows isotropically starting from the exposed seed layer portions. This results in a thermally and electrically conductive metal volume 61 as shown in FIG. 20 if the ALD or CVD is stopped before metal can further build up in the opening 55. Such a metal buildup is however allowable as well, up to a point where the opening 55 is completely or partially filled with metal. The volume 61 is located underneath both HBT fingers and bridges also the spacing between the HBT fingers. As in the other embodiments, the volume 61 enables improved heat removal from the HBT fingers compared to existing designs.

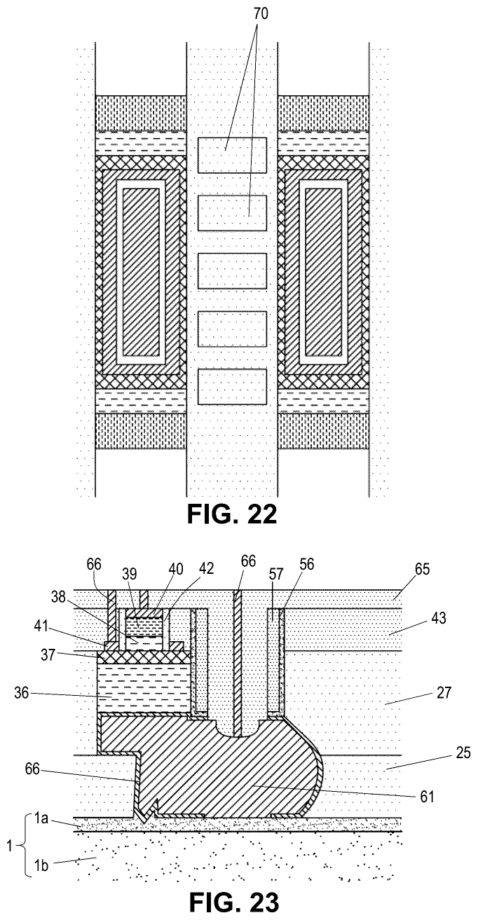

The stage shown in FIG. 20 may be followed as shown in FIG. 21 by depositing a pre-metal dielectric layer 65 and producing interconnect vias 66 through the layer, for contacting the emitter and base electrodes of the HBTs, and for contacting the metal volume 61, which acts as a common collector electrode for the HBTs. Alternatives to some of the above-described method steps are possible within the scope of the disclosure. For example, instead of producing an opening 55 that is aligned to the spacing between the HBTs, multiple smaller openings 70 can be produced in the spacing area, as illustrated in FIG. 22. Like the larger opening 55, these openings 70 pass through the dielectric layer 43 and partially into the template layer 27. The removal of the template layer and support layer portions between the subcollectors 35 and of the subcollectors 35 themselves (or at least a bottom portion thereof) then takes place through these openings 70. Also the deposition of the metal seed layer 60 and of the metal filling takes place through these openings 70. This embodiment does not require protecting the collectors and bases of the HBT fingers during the wet etch process.

Another embodiment is illustrated in FIG. 23, which shows the result of the method explained above for the case of two adjacent HBT fingers, but applied to a single finger HBT. The opening 55 is produced adjacent the HBT. The wet etching step removes part of the template layer 27 and the support layer 25, as well as the subcollector 35. It is apparent from FIG. 23 that the wet etching step includes the application of different etch recipes, a first recipe for removing the materials of layers 27 and 25 selectively with respect to the substrate and the subcollector 35, and a second recipe for removing the subcollector selectively with respect to the substrate and the dielectric layers 25 and 27.

The etch stop layer 56 and dielectric layer 57 are applied and have the same function as explained above. Material of the template and support layers is partially removed also in the direction away from the HBT location, resulting in a metal-filled cavity 61 that is partially located under the HBT, as shown in the drawing.

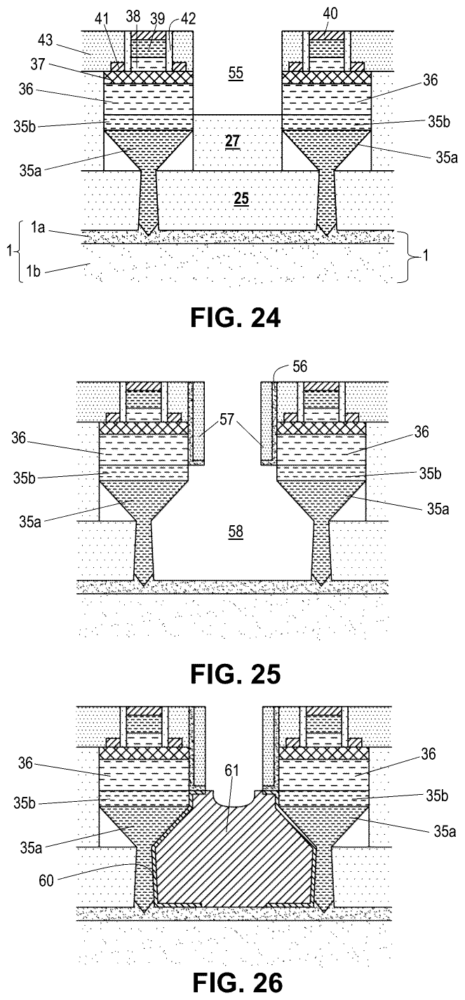

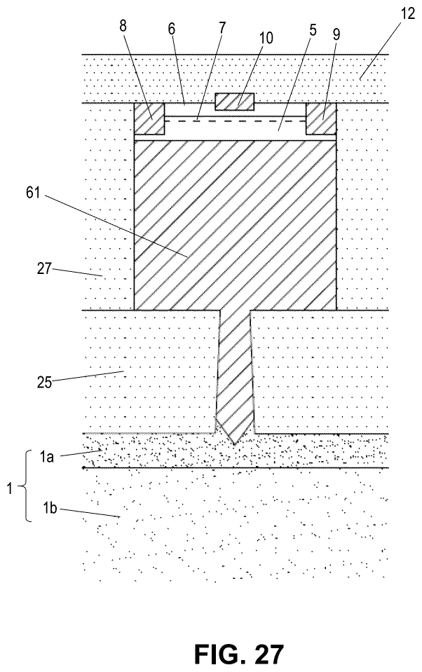

A further alternative is illustrated in FIGS. 24-26. In FIG. 24 it is seen that the HBT fingers have a slightly different structure compared to the embodiment of FIGS. 12-20. The subcollector now comprises a bottom part 35a and at top part 35b. According to an example, the bottom part 35a is formed of the poorly thermally conductive InGaAs and the top part is formed of the more thermally conductive InP. As seen also in FIG. 24, the opening 55 is produced to a lower depth compared to the embodiment of FIGS. 12-20: the bottom of the opening is more or less at the same level as the interface between the top subcollector part 35b and the collector 36. After this, the etch stop layer 56 and dielectric layer 57 are applied and the material of the template layer 27 and the support layer 25 is removed through the opening 55, resulting in the structure shown in FIG. 25, i.e. the creation of the cavity 58. At this point, rather than enlarging the cavity 58 by removing the subcollectors 35, the metal fill step, including deposition and patterning of the metal seed layer 60 is performed in the cavity 58, as illustrated in FIG. 26. The metal volume 61 is now in direct contact with the thermally conductive top part 35b of the subcollectors, and is thereby able to remove heat produced by the active layers of the HBT fingers. According to this embodiment therefore, a bottom portion of the mesa structure 2 is not removed and replaced with a highly thermally conductive material, but such a material is formed in a region directly adjacent to the bottom portion. As illustrated, the method according to this embodiment may be configured so that the highly thermally conductive volume 61 is formed adjacent a thermally conductive part of the mesa structure.

Therefore, according to some example methods, to create the cavity that is to be filled with highly thermally conductive material, either a bottom portion of the mesa structure is removed (as in FIGS. 3 and 8A/8B), or the bottom portion is removed together with a portion of dielectric material in a region directly adjacent to the bottom portion (as in FIGS. 17 and 23), or only the portion of dielectric material in a region directly adjacent to the bottom portion of the mesa structure is removed (as in FIG. 24). In every one of these three embodiments, the highly thermally conductive volume obtained by filling the cavity enhances considerably the heat transfer from the device comprising active layers in the upper portion of the mesa structure, to the substrate onto which the mesa structure has been processed.

It is also possible to produce a HEMT on a nanoridge structure and provide the HEMT with a highly thermally conductive volume 61 in accordance with the disclosure, as is illustrated in FIG. 24. The active layers and electrodes of the HEMT are numbered by the same reference numerals as in the case of the HEMT shown in FIG. 5. The method steps for producing this particular embodiment are the same as described for the HBT shown in FIGS. 9A and 9B.

The method is applicable to other semiconductor devices besides HBTs and HEMTs, for example PIN diodes and lasers.

Example embodiments also relate to a semiconductor component, for example an IC chip obtainable by applying example methods in the production process of the component on a semiconductor substrate, for producing one or more devices such as HBTs or III-V HEMTs in the FEOL portion of the chip. The component is characterized by the fact that one or more devices have active layers integrated in an isolated mesa structure comprising a highly thermally conductive volume configured to conduct heat from the active layers to the substrate.

While the invention has been illustrated and described in detail in the drawings and foregoing description, such illustration and description are to be considered illustrative and not restrictive. Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used. Any reference signs in the claims should not be construed as limiting the scope.

What is claimed is:

1. A semiconductor processing method comprising:
providing a substrate formed of a first semiconductor material;
producing a mesa structure on the substrate and in direct contact with the substrate, wherein the mesa structure is isolated on all lateral sides by dielectric material, and wherein active layers of a semiconductor device are integrated in an upper portion of the mesa structure;
producing one or more openings through the dielectric material without passing through the active layers;
forming a cavity by removing a bottom portion of the mesa structure through the one or more openings or removing the dielectric material in a region directly adjacent to the bottom portion of the mesa structure, wherein forming the cavity comprises using one or more etching steps configured to remove material relative to the substrate and relative to the active layers integrated in the upper portion; and
obtaining a thermally conductive volume by filling the cavity through the one or more openings with a material of high thermal conductivity, wherein the thermally conductive volume is configured to remove heat produced in one or more of the active layers of the device towards the substrate.

2. The method according to claim 1, wherein the mesa structure is formed of semiconductor materials that exhibit a lattice mismatch relative to the first semiconductor material.

3. The method according to claim 2, wherein the semiconductor materials exhibiting the lattice mismatch are III-V semiconductor materials.

4. The method according to claim 2, wherein the first semiconductor material is crystalline silicon.

5. The method according to claim 1, wherein the bottom portion of the mesa structure comprises at least part of a buffer layer formed on the substrate for compensating a lattice mismatch between the first semiconductor material and one or more semiconductor materials applied in the active device layers.

6. The method according to claim 1, wherein the dielectric material comprises:
a first dielectric-filled trench that surrounds the mesa structure on all lateral sides; and
a second dielectric-filled trench of lower depth than the first dielectric-filled trench, wherein the second dielectric-filled trench is positioned inside the first dielectric-filled trench.

7. The method according to claim 1, wherein producing the mesa structure comprises:
forming a nanoridge structure extending in a longitudinal direction; and
forming a first layer obtained by epitaxial growth of a second semiconductor material in:
a first trench extending in the longitudinal direction and passing through a dielectric support layer formed on the substrate; and
a second trench that is wider than the first trench and aligned thereto, wherein the second trench passes through a dielectric template layer formed on the support layer,
wherein the second semiconductor material is lattice mismatched relative to the first semiconductor material,
wherein, when growing above the first trench, the first layer expands to the width of the second trench,
wherein the aspect ratio of the first trench is configured so that the material growing above the first trench is substantially defect-free,
wherein further semiconductor layers are grown on the first layer to form the nanoridge structure,
wherein the production of the mesa structure comprises isolating a longitudinally arranged portion of the nanoridge structure so that the mesa structure comprises a portion of the first layer at the bottom of the mesa structure,
wherein, in the longitudinal direction, the mesa structure is isolated on both sides by an additional dielectric layer,
wherein, in a direction perpendicular to the longitudinal direction, the mesa structure is isolated on both sides by the support layer, the template layer, and the additional dielectric layer such that the dielectric material isolating the mesa structure on all sides comprises the materials of the additional dielectric layer, the support layer, and the template layer, and
wherein the bottom portion of the mesa structure comprises at least the portion of the first layer at the bottom of the mesa structure.

8. The method according to claim 7, wherein the one or more openings are produced on one or both sides of the mesa structure along the longitudinal direction, and wherein the one or more openings passing through the additional dielectric layer.

9. The method according to claim 7, wherein an etch stop layer is produced on the sidewalls of the second trench in the template layer, wherein the bottom portion of the mesa-structure is removed, and wherein, in addition to the removal of the bottom portion of the mesa-structure, the cavity is widened at the base of the cavity by removing portions of the support layer on both sides of the first trench by etching while the etch stop layer protects the material of the template layer.

10. The method according to claim 7, wherein the one or more openings are produced on one side of the mesa structure in the direction perpendicular to the longitudinal direction, wherein the one or more openings pass through the additional dielectric layer and partially through the template layer, and wherein the etching steps comprise at least etching the material of the template layer and the support layer selectively with respect to the additional dielectric layer and with respect to the substrate.

11. The method according to claim 10, wherein the mesa structure is one of a pair of adjacent mesa structures produced from a pair of mutually parallel nanoridges, wherein the one or more openings are made in the spacing between the mesa structures, and wherein the cavity is common to both mesa structures.

12. The method according to claim 11, wherein one opening is formed between the mesa structures, and wherein the width of the opening is aligned to the spacing between the mesa structures.

13. The method according to claim 1, wherein the semiconductor device is a heterojunction bipolar transistor (HBT) or a high-electron-mobility transistor (HEMT).

14. A semiconductor component comprising:
a semiconductor substrate;
a front end of line (FEOL) portion comprising active semiconductor devices on the semiconductor substrate;
a back end of line portion on the FEOL portion, wherein at least one of the semiconductor devices comprises active layers that are integrated in an upper portion of a mesa structure that is in direct contact with the semiconductor substrate, and wherein the mesa structure is isolated on all lateral sides by dielectric material; and
a highly thermally conductive volume extending at least partially between the active layers and the semiconductor substrate or directly adjacent to a bottom portion of the mesa structure.

15. The semiconductor component according to claim 14, wherein the at least one semiconductor device is a heterojunction bipolar transistor (HBT) or a high-electron-mobility transistor (HEMT).

16. A semiconductor component obtained by applying a semiconductor processing method, wherein the semiconductor processing method comprises:
providing a substrate formed of a first semiconductor material;
producing a mesa structure on the substrate and in direct contact with the substrate, wherein the mesa structure is isolated on all lateral sides by dielectric material, and wherein active layers of a semiconductor device are integrated in an upper portion of the mesa structure;
producing one or more openings through the dielectric material without passing through the active layers;
forming a cavity by removing a bottom portion of the mesa structure through the one or more openings or removing the dielectric material in a region directly adjacent to the bottom portion of the mesa structure, wherein forming the cavity comprises using one or more etching steps configured to remove material relative to the substrate and relative to the active layers integrated in the upper portion; and
obtaining a thermally conductive volume by filling the cavity through the one or more openings with a material of high thermal conductivity, wherein the thermally conductive volume is configured to remove heat produced in one or more of the active layers of the device towards the substrate.

17. The semiconductor component according to claim 16, wherein the mesa structure is formed of semiconductor materials that exhibit a lattice mismatch relative to the first semiconductor material.

18. The semiconductor component according to claim 17, wherein the semiconductor materials exhibiting the lattice mismatch are III-V semiconductor materials.

19. The semiconductor component according to claim 17, wherein the first semiconductor material is crystalline silicon.

20. The semiconductor component according to claim 16, wherein the bottom portion of the mesa structure comprises at least part of a buffer layer formed on the substrate for compensating a lattice mismatch between the first semiconductor material and one or more semiconductor materials applied in the active device layers.
